(19) United States
(12) Patent Application Publication
(10) Pub. No.: US 2025/0054557 A1
(43) Pub. Date: Feb. 13, 2025

(54) CONTROL METHODS, PARAMETER CALCULATION METHODS, MEMORY AND MEMORY SYSTEMS

(71) Applicant: Yangtze Memory Technologies Co., Ltd., Wuhan (CN)

(72) Inventors: SanShan Jiao, Wuhan (CN); Ling Chu, Wuhan (CN); HuaZheng Wei, Wuhan (CN)

(21) Appl. No.: 18/507,993

(22) Filed: Nov. 13, 2023

(30) Foreign Application Priority Data
Aug. 9, 2023 (CN) 202311000910.5

(51) Int. Cl. G11C 16/34; G11C 16/26

(52) U.S. Cl. CPC G11C 16/3495; G11C 16/26

(57) ABSTRACT

The present disclosure provides a control method, a parameter calculation method, a memory and a memory system. The memory includes a plurality of memory cells and a plurality of transistors. The plurality of memory cells correspond to the plurality of transistors. The control method includes: reading the plurality of transistors based on the verification read voltage to obtain the read failure count. Values of the read failure count correspond to different product stages of the memory. A first voltage is stored in the plurality of first transistors. The voltage value of the first voltage is equal to that of the verification read voltage. A product stage is associated with data processing times for multiple memory cells. A destination entry is selected from the plurality of entries according to the value of the read failure count.

### REFERENCE TO RELATED APPLICATIONS

This application claims priority to and the benefit of Chinese Patent Application 202311000910.5, filed on Aug. 9, 2023, which is hereby incorporated by reference in its entirety.

### TECHNICAL FIELD

The present disclosure relates to the technical field of chip storage, and in particular to a control method, a parameter calculation method, a memory and a memory system.

### BACKGROUND

A memory system includes memory. The memory may be flash memory (NAND). Memory cells in flash memory can be used to store data. However, the performance and lifespan of the memory cell will change due to the impact of data processing times. The data processing times includes data writing times, data erasing times, and the like. After the performance of the memory cell changes, the processing parameters based on which data processing is performed on the memory cell will also change.

### BRIEF DESCRIPTION OF THE DRAWINGS

In order to illustrate the technical solutions in the present disclosure more clearly, the accompanying drawings required in some implementations of the present disclosure will be briefly introduced in the following. Obviously, the accompanying drawings in the following description are only figures of some implementations of the present disclosure. For those of ordinary skill in the art, other drawings can also be obtained based on these drawings. In addition, the drawings in the following description can be regarded as schematic diagrams, and are not limitations on the actual size of the product involved in the implementations of the present disclosure, the actual process of the method, the actual timing of signals, and the like.

FIG. 1 is a schematic diagram of modules of a memory according to some implementations;

FIG. 2 is a schematic diagram of modules of a memory array according to some implementations;

FIG. 3 is a first schematic flowchart of a parameter calculation method according to some implementations;

FIG. 4 is a second schematic flow diagram of a parameter calculation method according to some implementations;

FIG. 5 is a schematic diagram of the distribution of threshold voltages of a first voltage set as the data processing times varies according to some implementations;

FIG. 6 is a third schematic flowchart of another parameter calculation method according to some implementations;

FIG. 7 is a first schematic flowchart of a control method according to some implementations;

FIG. 8 is a second schematic flow diagram of another control method according to some implementations;

FIG. 9 is a first schematic diagram of modules of a memory system according to some implementations;

FIG. 10 is a second schematic diagram of modules of another memory system according to some implementations; and

FIG. 11 is a schematic diagram of modules of an electronic device according to some implementations.

### DETAILED DESCRIPTION

The technical solutions in some implementations of the present disclosure will be clearly and completely described below in conjunction with the accompanying drawings. Apparently, the described implementations are only some of the implementations of the present disclosure, but not all of them. All other implementations obtained by persons of ordinary skill in the art based on the implementations provided in the present disclosure belong to the protection scope of the present disclosure.

In describing the present disclosure, it is to be understood that the orientations or positional relationships indicated by the terms such as “center”, “upper”, “lower”, “front”, “rear”, “left”, “right”, “vertical”, “horizontal”, “top”, “bottom”, “inner”, “outer”, and/or the like are based on the orientations or positional relationships shown in the drawings, and are only for the convenience of describing the present disclosure and simplifying the description, rather than indicating or implying referred devices or elements must have a particular orientation, be constructed, and operate in a particular orientation, and therefore should not be construed as limiting the present disclosure.

Unless the context requires otherwise, the term “comprising” throughout the specification and claims is interpreted in an open and inclusive sense, i.e., “including, but not limited to”. In the description of the specification, the terms “one implementation”, “some implementations”, “exemplary implementation”, “exemplarily” or “some examples” are intended to indicate particular features, structure, material or characteristic associated with the implementation or examples is included in at least one implementation or example of the present disclosure. Schematic representations of the above terms are not necessarily referring to the same implementation or example. Furthermore, the particular features, structures, materials or characteristics described may be included in any suitable manner in any one or more implementations or examples.

Hereinafter, the terms “first” and “second” are used for descriptive purposes only, and cannot be understood as indicating or implying relative importance or implicitly specifying the quantity of indicated technical features. Thus, a feature defined as “first” and “second” may explicitly or implicitly include one or more of these features. In the description of the implementations of the present disclosure, unless otherwise specified, “plurality” means two or more.

In describing some implementations, the expressions “coupled” and “connected” and their derivatives may be used. For example, the term “connected” may be used in describing some implementations to indicate that two or more elements are in direct physical or electrical contact with each other. As another example, the term “coupled” may be used in describing some implementations to indicate that two or more elements are in direct physical or electrical contact. However, the term “coupled” may also mean that two or more elements are not in direct contact with each other, but still cooperate or interact with each other. The implementations disclosed herein are not necessarily limited to the disclosure herein.

“At least one of A, B and C” has the same meaning as “at least one of A, B or C” and both include the following combinations of A, B and C: A only, B only, C only, A and B A and C, B and C, and A, B and C.

“A and/or B” includes the following three combinations: A only, B only, and A and B.

The use of “adapted to” or “configured to” herein means open and inclusive language that does not exclude devices that are adapted to or configured to perform additional tasks or procedure.

Additionally, the use of “based on” is meant to be open and inclusive, as a process, procedure, calculation, or other action that is “based on” one or more stated conditions or values may in practice be based on additional conditions or beyond stated values.

To ensure the reliability of the flash memory, during the data processing process of the memory, it is necessary to record each data processing operation and store the data processing times of the relevant memory cells, so as to adjust the processing parameters of the data processing according to the corresponding data processing times. However, in this implementation, the recording of the data processing times will occupy the processing time of the program and reduce the processing performance of the memory. In addition, recording these data processing times will also occupy a certain storage space of the memory.

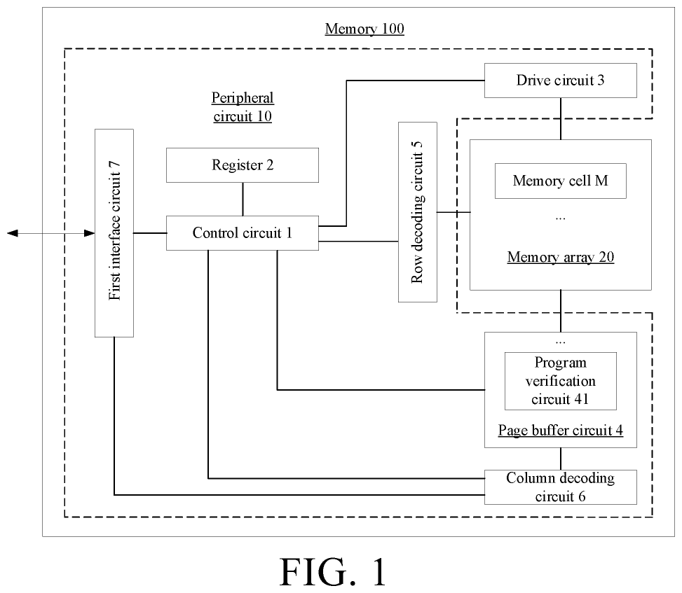

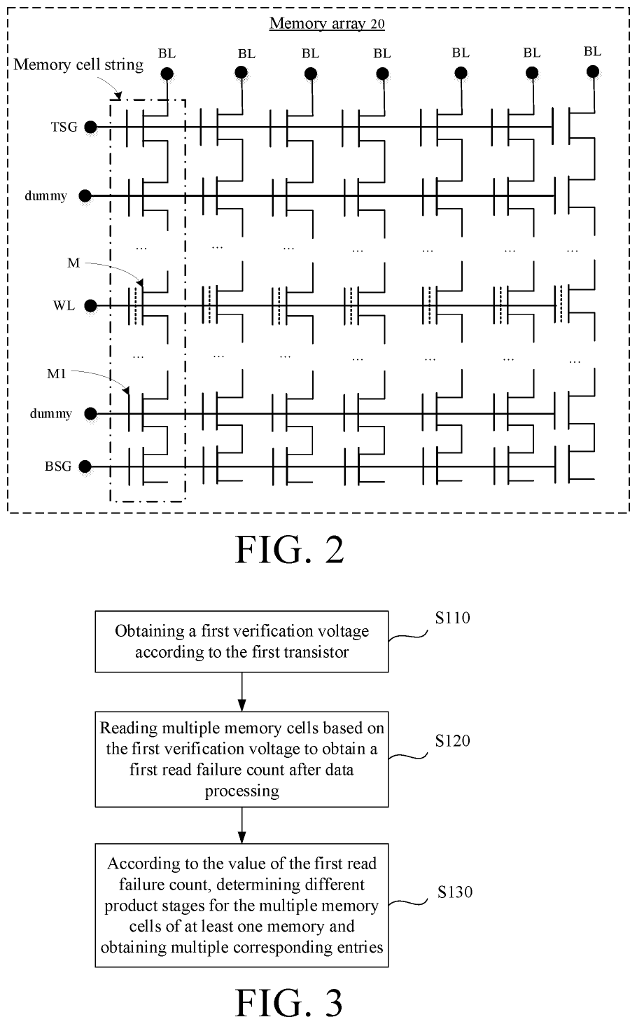

An implementation of the present disclosure provides a memory. As shown in FIG. 1, the memory 100 includes a peripheral circuit 10 and a memory array 20. The peripheral circuit 10 includes a control circuit 1, a register 2, a drive circuit 3, a page buffer circuit 4, a row decoding circuit 5, a column decoding circuit 6 and a first interface circuit 7. The page buffer circuit 4 also includes a program verification circuit 41. As shown in FIG. 1 and FIG. 2, the memory array 20 includes a plurality of memory cells M. The control circuit 1 is coupled with the register 2, the drive circuit 3, the page buffer circuit 4, the row decoding circuit 5, the column decoding circuit 6, the memory array 20 and the first interface circuit 7 respectively. The drive circuit 3 is further coupled to the page buffer circuit 4, the row decoding circuit 5 and the column decoding circuit 6 respectively. The column decoding circuit 6 is further coupled to the first interface circuit 7. The memory 100 is coupled with peripheral devices via the first interface circuit 7.

As an example, as shown in FIG. 2, a plurality of memory cell strings are included in the memory array 20 of the memory 100, and each memory cell string includes a Top Select Gatecut (TSG) transistor, a dummy memory transistors, memory cells M, and Bottom Select Gatecut (BSG) transistors, and the like. The TSG transistor, the dummy memory transistor and the BSG transistor in each memory cell string are coupled to a plurality of memory cells M via a Bit Line (BL). The TSG transistor and the BSG transistor are to assist in selection of different bit lines BL and the like. The gate of each of the TSG transistor, BSG transistor, dummy memory transistor and memory cell M is coupled to a corresponding different Word Line (WL). Performing data reading processing and the like on the selected transistors can be realized by performing operations such as charging and discharging on the selected bit line BL and the selected WL. The dummy memory transistor can implemented to offer a stable working environment for the memory cell M at the edge of the memory array 20 (i.e., the same working environment as other non-edge memory cells M). At the same time, in some examples, the dummy memory transistor may further store related operating data and the like implemented by some functions of the memory 100.

In some possible implementations, the program verification circuit 41 may be a sense latch in the page buffer circuit 4.

In some possible implementations, the memory 100 may be a flash (NAND) memory. In some examples, the memory cell M in the memory array 20 may be a Single Level Cell (SLC), a Multi Level Cell (MLC), a Triple Level Cell (TLC), Quadruple Level Cell (QLC), Penta Level Cell (PLC), etc. In the memory cell M based on SLC, MLC, TLC, etc., as the number of levels increases, the number of data bits that can be stored in each memory cell M also increases. Parameter table entries are stored in the register 2. The parameter entry is to record processing parameters for the memory 100 to perform data processing operations.

Data processing operations of the memory 100 include programming operations, data reading operations, erasing operations, and the like. The programming operation of the memory 100 can be divided into two types: single-voltage programming and step programming. Single-voltage programming refers to programming the selected memory cell M with a larger threshold voltage. The programming speed of the single-voltage programming is faster, but the problem of over-programming is prone to occur, which reduces the reliability of the memory 100. The step programming refers to the programming operation through multi-cycle programming. Each programming cycle includes a program stage and a Program Verify (PV) stage. In the multi-cycle programming, program voltages with different voltage values are applied multiple times at a certain interval to perform processing operations in the program stage and the verify stage for multiple cycles to the selected memory cell M. The number of program stages and verify stages is related to the number of erased and programmed states of the memory cell M. The corresponding data in the erased state takes the value 0. The programmed state corresponds to data values of 1 and above. Typically, multi-cycle programming includes at least one coarse programming first and a final fine programming. In coarse programming, the processing operations of the program stage and the verify stage are implemented at smaller intervals. The processing operations of the program stage and the verify stage are implemented at relatively large intervals in the last fine programming.

Taking the memory cell M being an SLC as an example, the SLC has a data bit, including data values of 0 and 1, corresponding to one erased state and one programmed state. For SLC, the programming operation for multiple memory cells M in a certain storage area (for example, a memory block or a memory page) can be realized by two cycle programmings in the manner of cycle programming. When programming a plurality of memory cells M, the control circuit 1 selects the plurality of memory cells M in the storage area based on the drive circuit 3, the row decoding circuit 5, the column decoding circuit 6 and the like in the first program stage. First, it is necessary to program the selected plurality of memory cells M with a program start voltage as the initial threshold voltage. In the program verify stage after the first program stage, verification read is performed on the selected multiple memory cells M based on the verify start voltage, and a plurality of first indication signals are output to the control circuit 1 by the program verification circuit 41 in the page buffer circuit 4. The plurality of first indication signals are to indicate verification read results of the corresponding plurality of memory cells M. When a memory cell M passes the verification, it means that the memory cell M has been programmed into the target programmed state, and the subsequent program stage stops programming it. When a certain memory cell M fails the verification, it means that the memory cell M has not been programmed into the target programmed state, and the subsequent program stage continues to program it. The control circuit 1 can determine a Fail Bit Count (FBC) according to the multiple first indication signals. FBC is to indicate the number of memory cells M that have not passed verification. In the program stage of the second fine programming, the value of the program start voltage is increased with a certain program offset voltage value, and the memory cells M that have not passed the verification are programmed. Similarly, in the application scenarios of MLC, TLC, etc., there are more programmed states compared with the application scenarios of SLC. More cycle programming times are also required. In each cycle programming, compared with the previous cycle programming, the magnitude of the verification read voltage in the verify stage is increased with a certain read offset voltage value. As an example, the magnitudes of read offset voltage values in two adjacent cycle program stages may be the same or different. The magnitudes of the program offset voltage values in two adjacent cycle program stages may be the same or different.

Because the performance of each memory cell M in the NAND is affected by the number of data processing operations, such as program operations, erase operations, etc., that will cause wear of the memory cell M and reduce the life of the memory cell M. According to the different types of the memory cell M, the times the memory cell M can perform data processing operations is also different. Generally, as the number of data bits of the memory cell M increases, the number of data processing operations that can be performed decreases accordingly. For example, some SLC-based memories 100 can perform data processing operations up to hundreds of thousands of times, while some TLC, QLC or PLC-based memories 100 can only perform data processing operations for hundreds up to thousands of times. As the number of programming times of the memory cell M increases, the performance of the memory cell M changes, and the processing parameters for performing data processing operations on the memory cell M also need to be adjusted. In order to ensure the reliability of the memory 100, different entries need to be set for the memory cells M with different data processing times, and each entry records the processing parameters required for data processing operations to the memory cell M corresponding to the different data processing times. In practical applications, the data processing times of multiple memory cells M in the relevant storage area are recorded after each data processing. When subsequent data processing is performed on the multiple memory cells M in the storage area, a corresponding entry is selected to perform this data processing operation according to the recorded data processing times. For the memory 100, the programming duration (t_{PROG}) is an important index to measure its performance. However, in this implementation, the recording the data processing times will occupy the processing time of the program and reduce the processing performance of the memory. In addition, recording these data processing times will also occupy a certain storage space of the memory.

To improve the processing performance of the memory 100 on the basis of ensuring the reliability of the memory 100 in different product stages, an implementation of the present disclosure provides a parameter calculation method, which is performed based on the memory 100 including the structures shown in FIG. 1 and FIG. 2. As shown in FIG. 3, the parameter calculation method includes the following operations S110-S130:

S110. Obtaining a first verification voltage according to the first transistor M1.

In some possible implementations, the performance change of the first transistor is positively correlated with the data processing times of the memory cell M. The first verification voltage is used in performing program verification on the plurality of memory cells M after performing data processing on the plurality of memory cells M. In the implementation of the present disclosure, the performance change of the first transistor M1 is positively correlated with the data processing times of the memory cell M. Therefore, the first verification voltage can be obtained according to the performance change of the first transistor M1 which is not a memory cell M when the memory cell M is subjected to different data processing times. Verification reading is performed on the memory cell M based on the first verification voltage, and obtained value of the first read failure count can also indicate the data processing times of the memory cell M.

As an example, as shown in FIG. 2, the first verification voltage may be obtained based on one or more memories 100. The one or more memories 100 are memories that have subjected to data processing operations. In actual data processing operations, the performances of TSG transistors, BSG transistors, and dummy memory transistors will all change as the number of data processing increases. Therefore, at least one of the TSG transistor, the BSG transistor and the dummy memory transistor, etc. can be used as the first transistor M1 to obtain the first verification read voltage.

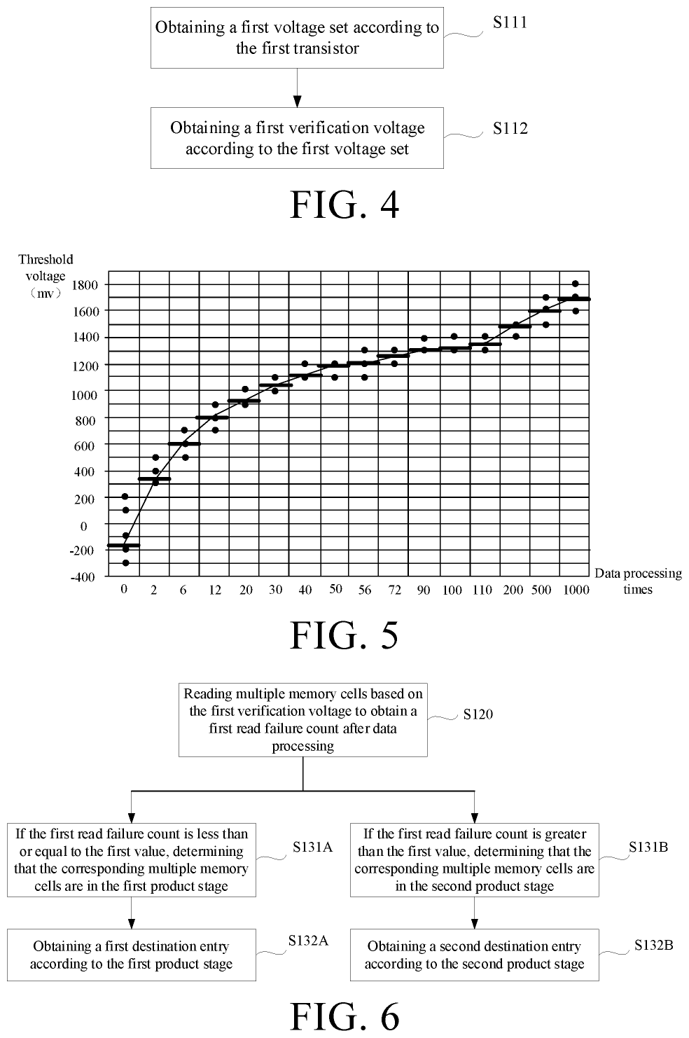

In some possible implementations, as shown in FIG. 4, operation S110 specifically includes the following operations S111-S112:

S111. Obtaining a first voltage set according to the first transistor M1.

As an example, when the data processing times of the memory cell M in the memory array 20 of the memory 100 increase, the performance of the first transistor M1 which is not a memory cell M will also change. As the performance changes, the threshold voltage of the first transistor M1 also changes. Changes in the threshold voltage of the first transistor M1 at different data processing times are acquired to obtain multiple threshold voltages. The multiple threshold voltages include the threshold voltages corresponding to the first transistor M1 at multiple different programming times. The first voltage set is obtained by merging multiple threshold voltages.

S112. Obtaining a first verification voltage according to the first voltage set.

In some possible implementations, changes in the multiple threshold voltages in the first voltage set are associated with the data processing times. According to the distribution of multiple threshold voltages in the first voltage set at different product stages, the corresponding threshold voltage is selected as the first verification voltage.

As an example, the magnitude of the first verification voltage is between the first threshold voltage and the second threshold voltage. The first threshold voltage is the threshold voltage corresponding to the first transistor M1 at the first programming times. The first programming times belongs to the programming times corresponding to the first product stage. The second threshold voltage is the threshold voltage corresponding to the first transistor M1 at the second programming times. The second programming times belongs to the programming times corresponding to the second product stage.

As an example, as shown in FIG. 5, it schematically shows the change of the first voltage set obtained for the dummy memory transistor of a certain type of memory 100 and the data processing times of the memory 100. According to the data processing times of the memory cell M, the memory 100 can be divided into two or more product stages according to the data processing times. In the range of data processing times from 0 to 100, the threshold voltage Vth of the first transistor M1 varies greatly, and this section can be used for the product delivery test of the memory 100 and the like. In the range of data processing times from 100 to 1000, the threshold voltage Vth of the first transistor M1 still changes, but the degree of change gradually becomes flat. This stage can be regarded as the first product stage of the memory 100. The first product stage is the delivery stage of the memory 100, that is, the beginning of life (BOL) stage. When the number of data processing times is more than 1000, the change of the threshold voltage Vth is small, but the memory 100 may have problems such as device aging, such as transistor aging caused by hot carrier injection in the transistors in the memory 100 and the like. This stage can be divided into the second product stage of the memory 100, namely the end of life (EOL). Similarly, the threshold voltage of the memory cell M changes with the data processing times accordingly.

As an example, the first programming times is one-tenth of the second programming times. In the implementations of the present disclosure, when the memory 100 is divided into EOL and BOL, the initial programming times of BOL is generally one-tenth of the initial programming times of EOL. As an example, the initial programming times of BOL (that is, 100 times) may be selected as the first programming times. The initial programming times of EOL (that is, 1000 times) is selected as the second programming times. As shown in FIG. 5, the value of the threshold voltage corresponding to the first programming times is 1400 mv, that is, 1.4V. The value of the threshold voltage corresponding to the second programming times is 1600 mv, that is, 1.6V. A certain threshold voltage can be selected between 1.4V-1.6V as the first verification read voltage. In some examples, an average value of 1.5V may be taken as the first verification read voltage. In some examples, the first verification read voltage can be obtained by taking the mode. In some examples, a certain threshold voltage may also be calculated based on other methods as the first verification read voltage.

S120. Reading a plurality of first transistors M1 based on the first verification read voltage to obtain a first read failure count.

In the implementation of the present disclosure, after the value of the first verification read voltage is determined, the first verification read voltage is used to read a plurality of first transistors M1, and the first read failure count corresponding to the plurality of first transistors M1 are obtained.

S130. Determining different product stages for the multiple memory cells M of at least one memory 100 according to the value of the first read failure count and obtaining multiple corresponding entries.

In some possible implementations, as shown in FIG. 6, the operation S130 includes the following operations S131A-S132A, and operations S131B-S132B:

S131A. If the first read failure count is less than or equal to the first value, determining that the corresponding memory cells are in the first product stage.

S132A. Obtaining a first destination entry according to the first product stage.

S131B. If the first read failure count is greater than the first value, determining that the corresponding memory cell is in the second product stage.

S132B. Obtaining a second destination entry according to the second product stage.

In an implementation of the present disclosure, a first value may be set, and the first value is a reference value for judging the read failure count. In the case that the first verification read voltage is the same, the first product stage and the second product stage are determined by the read failure count.

In the implementations of the present disclosure as shown in FIG. 3, FIG. 4 and FIG. 6, the first voltage set is obtained by obtaining threshold voltages of a plurality of first transistors M1. Multiple product stages of the memory 100 are determined based on different data processing times of the multiple memory cells M, and a first verification voltage is obtained according to threshold voltages at the multiple product stages. The first verification voltage is used as the verification read voltage of the plurality of first transistors M1 to perform verification reading on the plurality of first transistors M1 to obtain a first read failure count. According to the first read failure count and the data processing times, the product stages are re-determined for the multiple memory cells M, corresponding processing parameters are designed for the re-determined product stages, and the multiple processing parameters are carried on multiple entries.

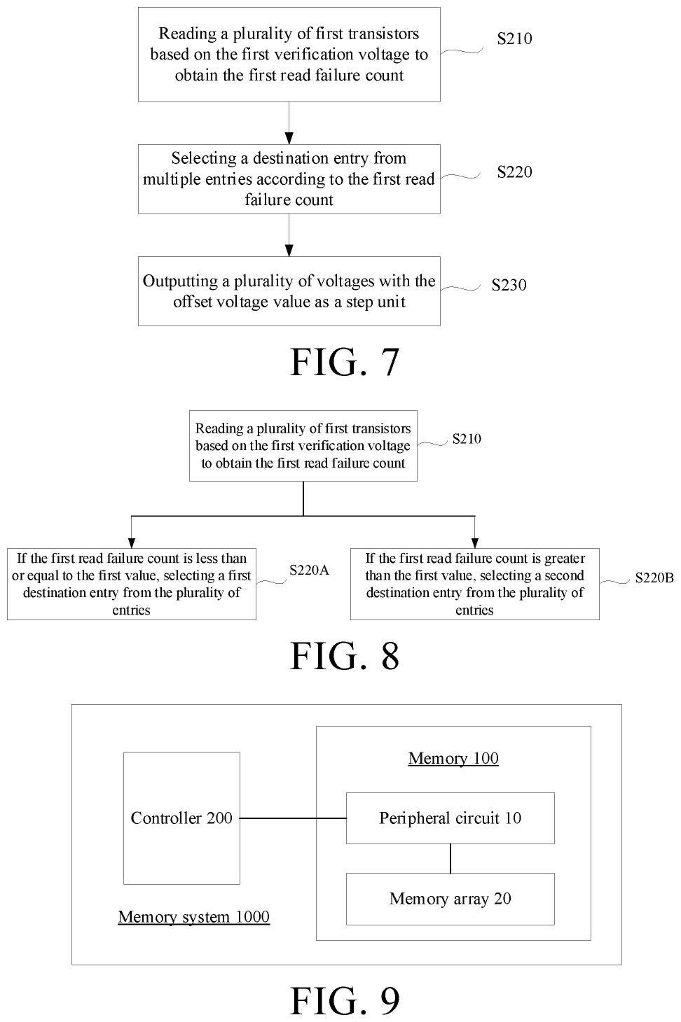

Implementations of the present disclosure further provide a control method based on the memory 100 including the structure shown in FIG. 1 and FIG. 2. As shown in FIG. 7, the control method includes the following operations S210-S230:

S210. Reading a plurality of first transistors based on the first verification read voltage to obtain the first read failure count.

As an example, values of the first read failure count correspond to different product stages of the memory. The plurality of memory cells corresponds to the plurality of first transistors. A first voltage is stored in the plurality of first transistors. The voltage value of the first voltage is equal to that of the first verification read voltage. A product stage is associated with data processing times for multiple memory cells. In an implementation of the present disclosure, a first voltage is stored in the first transistor M1, and the voltage value of the first voltage is equal to that of the first verification read voltage. Verification reading on performed on the multiple first transistors M1 through the first verification read voltage, and the first read failure count is obtained through the verification read. The product stages corresponding to the plurality of memory cells M are determined according to the magnitude of the first read failure count.

As an example, as shown in FIG. 1 and FIG. 2, the drive circuit 3 is configured to: output a first verification read voltage to a plurality of first transistors M. The first verification read voltage is to turn on the plurality of first transistors M1 for verifying read. The program verification circuit 41 is configured to output a plurality of first indication signals to the control circuit 1. The plurality of first indication signals are to indicate the first read failure count after the verification read of the plurality of first transistors M1. Values of the first read failure count correspond to different product stages of the plurality of memory cells M. The product stage is associated with the data processing times of the plurality of memory cells M.

In some examples, the first verification read voltage is a voltage value obtained according to the first voltage set. The first voltage set includes a plurality of threshold voltages. The multiple threshold voltages include the threshold voltages corresponding to the multiple first transistors M1 at multiple different data processing times. In some examples, the magnitude of the first verification read voltage is between the first threshold voltage and the second threshold voltage. The first threshold voltage is the corresponding threshold voltage of the first transistor at the first programming times. The first programming times belong to the programming times corresponding to the first product stage. The second threshold voltage is the corresponding threshold voltage of the first transistor at the second programming times. The second programming times belong to the programming times corresponding to the second product stage. In some examples, the first programming times is one tenth of the second programming times. In the implementations of the present disclosure, for the relevant descriptions about the specific technical principles and technical effects of the values of first verification read voltage being obtained according to the first voltage set, reference may be made to the relevant descriptions in the above-mentioned implementation of the parameter calculation method, which will not be repeated herein.

In some examples, the processing parameters also include a program start voltage and/or a verify start voltage.

In some examples, the first transistor M1 is a program selection transistor or a dummy memory transistor.

S220. Selecting a destination entry from multiple entries according to the value of the first read failure count.

In some possible implementations, as shown in FIG. 1 and FIG. 2, the control circuit 1 is configured to: select a destination entry from multiple entries in the register 2 according to the value of the first read failure count. The multiple entries are to record processing parameters for data processing of the multiple memory cells M. Processing parameters include offset voltage values. In the implementation of the present disclosure, after inputting a plurality of first indication signals, the control circuit 1 may determine the first read failure count after performing verification reading on the plurality of first transistors M1 based on the first verification read voltage. The product stages corresponding to the current multiple memory cells M can be determined according to the first read failure count, and the destination entry is selected from the multiple entries in the register 2 according to the determined product stage. The destination entry is the entry corresponding to the determined product stage. Compared with the scheme of recording the data processing times multiple times and storing the result of the data processing times in the operation of cycle programming, and then reading the result of the data processing times to select the destination entry during data processing, in the implementation of the present disclosure, by setting the first verification read voltage for the memory 100, the first read failure counts corresponding to the plurality of memory cells M in the memory 100 are obtained based on the first verification read voltage, and it is directly determined according to the value of the first read failure counts that the plurality of memory cells M correspond to a certain product stage of the memory 100. Moreover, subsequent data processing operations are performed for selecting the corresponding destination entry. In the implementation of the present disclosure, the operation of performing the corresponding recording of the times after each data processing operation is avoided. Taking a memory cell M being an SLC as an example, it is only necessary to perform a read operation based on the first verification read voltage to confirm the product stages corresponding to the multiple memory cells M. In the implementation of the present disclosure, the program operation for the memory 100 to record the number of data processing operations is avoided, the processing time of the memory 100 is reduced, and the processing speed of the data processing operations is improved. In addition, the memory 100 does not need to continuously store and record the processing times, which reduces the occupation of storage resources of the memory 100.

In some possible implementations, as shown in FIG. 8, operation S220 may include the following operations S220A or S220B:

S220A. If the first read failure count is less than or equal to the first value, selecting a first destination entry from the plurality of entries.

S220B. If the first read failure count is greater than the first value, selecting a second destination entry from the plurality of entries.

As an example, as shown in FIG. 1, the control circuit 1 is further configured to: if the first read failure count is less than or equal to the first value, select the first entry from the plurality of entries, where the first destination entry corresponds to the first product stage of a plurality of memory cells M. If the first read failure count is greater than the first value, a second destination entry is selected from the plurality of entries. The second destination entry corresponds to the second product stage of the plurality of memory cells M. In the implementations of the present disclosure, corresponding entries are respectively designed according to the first product stage and the second product stage. In actual programming, a program verification operation is performed by using the first verification read voltage, the corresponding first read failure count is obtained, and the first read failure count is compared with a preset first value. When the first read failure count is less than or equal to the first value, it means that the memory 100 is in the first product stage at this time, and the first destination entry corresponding to the first product stage can be acquired. When the first read failure count is greater than the first value, it means that the memory 100 is in the second product stage at this time, and the second destination entry corresponding to the second product stage can be acquired.

S230. Outputting a plurality of voltages with the offset voltage value as a step unit.

In some possible implementations, as the data processing times increases, the performance of the memory cell M will change, for example, a shift of the threshold voltage for turning on the memory cell M, and the like. Therefore, in order to ensure the reliability of data processing operations on the memory 100, different product stages may be determined for the memory 100 according to the data processing times of the memory cell M. Different processing parameters are configured for different product stages, and these processing parameters are stored in register 2 in the form of multiple table entries. An offset voltage value may be recorded in each entry. The offset voltage value may be a relative offset voltage value of different parameters related to the threshold voltage Vth, for example, the program offset voltage value corresponding to the program voltage during different times of cycle programming under cycle programming, or the read offset voltage value corresponding to the verification read voltage during different times of cycle programming, or other offset voltage value of the voltage associated with the threshold voltage Vth of the memory cell M.

As an example, the plurality of voltages may be program voltages required for cycle programming. The offset voltage value includes a program offset voltage value between a plurality of program voltages in the cycle programming. The processing parameters may also include a program start voltage value. The control circuit 1 obtains the program start voltage value and the program offset voltage value according to the target table entry, and controls the drive circuit 3 to generate a plurality of program voltages according to the program start voltage value and the program offset voltage value, so as to perform multiple programming operations on the plurality of memory cells M.

As an example, the plurality of voltages may be verification read voltages required for cycle programming. The offset voltage value includes a read offset voltage value between a plurality of verification read voltages in the cycle programming. The processing parameters may also include verify start voltage value. The control circuit 1 obtains the verify start voltage value and the read offset voltage value according to the destination entry, and controls the drive circuit 3 to generate a plurality of verification read voltages according to the program start voltage value and the program offset voltage value, so as to perform verification on multiple programming of multiple memory cells M.

In the implementation of the present disclosure as shown in FIG. 7 and FIG. 8, the confirmation of the product stage of the memory cell M can be realized through a verification read operation. By selecting corresponding entries for different product stages, data processing performance can be improved in the BOL stage of the product of the memory 100 (such as speeding up the processing of cycle programming), and the reliability of data processing can be improved in the EOL stage (such as the reliability of reading data).

Implementations of the present disclosure provide a control method, a parameter calculation method, a memory and a memory system. In the memory array of the memory, a plurality of memory cells and a plurality of first transistors are included. The performance change of the first transistor is associated with the data processing times of the corresponding plurality of memory cells. Therefore, the first verification read voltage can be obtained based on the threshold voltage of the first transistor. Verification reading are performed on the plurality of first transistors by using the first verification read voltage to obtain a first read failure count. The value of the first read failure count is also associated with the data processing times of multiple memory cells. Therefore, the value of the first read failure count can be used to determine different product stages for multiple memory cells, and the corresponding entry can be designed. Processing parameters for performing data processing operations on memory cells at different product stages are carried by different entries. In the subsequent operation of the memory, it is only necessary to perform a program verification operation on the first transistor to confirm the current product stage of the multiple memory cells. The implementations of the present disclosure do not need to record and store data processing times after each data processing operation, which can improve memory processing performance, reduce memory processing time, and avoid occupying of storage space from recording data processing times.

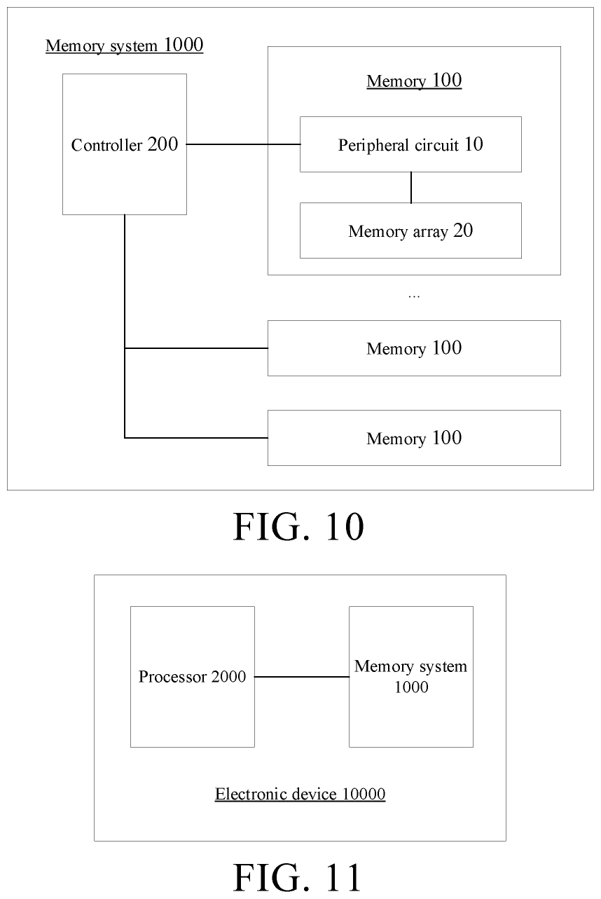

Implementations of the present disclosure also provide a memory system, as shown in FIG. 9 and FIG. 10. FIG. 9 is a block diagram of a memory system according to some implementations. FIG. 10 is a block diagram of a memory system according to other implementations.

Referring to FIG. 9 and FIG. 10, some implementations of the present disclosure also provide a memory system 1000, and the memory system 1000 includes a controller 200 and the memory 100 in some implementations above. The controller 200 is coupled to the memory 100 to control the memory 100 to store data.

The memory system 1000 can be integrated into various types of storage devices, for example, included in the same package (for example, Universal Flash Storage (referred to as UFS) package or Embedded Multi Media Card (referred to as eMMC) package. That is to say, the memory system 1000 can be applied and packaged into different types of electronic products, for example, mobile phones (such as cell phones), desktop computers, tablet computers, notebook computers, servers, vehicle-mounted devices, game consoles, printers, positioning device, wearable device, smart sensor, power bank, Virtual Reality (referred to as VR) device, Augmented Reality (referred to as AR) device or any other suitable electronic device having storage therein.

In some implementations, referring to FIG. 9, the memory system 1000 includes a controller 200 and a memory 100, and the memory system 1000 may be integrated into a memory card.

The memory card includes any one of PC card (PCMCIA, personal computer memory card international association), Compact Flash (referred to as CF) card, Smart Media (referred to as SM) card, memory stick, Multimedia Card (referred to as MMC), Secure Digital Memory Card (referred to as SD) card, and UFS.

In some other implementations, referring to FIG. 10, a memory system 1000 includes a controller 200 and multiple memories 100, and the memory system 1000 is integrated into Solid State Drives (referred to as SSDs).

In the memory system 1000, the controller 200 is configured to operate in a low duty-cycle environment in some implementations, for example, SD card, CF card, Universal Serial Bus (referred to as USB) flash memory drives or other media used in electronic devices such as personal calculators, digital cameras, mobile phones, etc.

In other implementations, the controller 200 is configured for operation in a high duty-cycle environment SSD or eMMC used for data storage in mobile devices such as smartphones, tablets, laptops, and enterprise storage array.

In some implementations, the controller 200 may be configured to manage data stored in the memory 100, and communicate with an external device (e.g., a host). In some implementations, the controller 200 can be further configured to control operations of the memory 100, such as read, erase and program operations. In some implementations, the controller 200 may also be configured to manage various functions related to data stored or to be stored in the memory 100, including at least one of bad block management, garbage collection, logical to physical address translation, wear leveling, etc. In some implementations, the controller 200 is further configured to process error correction codes on data read from or written to the memory 100.

Of course, the controller 200 can also perform any other suitable functions, such as formatting the memory 100. For example, the controller 200 can communicate with external devices (e.g., a host) via at least one of various interface protocols.

It should be noted that the interface protocols include at least one of USB protocol, MMC protocol, Peripheral Component Interconnect (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, and Firewire protocol.

Some implementations of the present disclosure further provide any one of an electronic device. Electronic devices can be cell phones, desktop computers, tablet computers, laptops, servers, in-vehicle devices, wearable devices (such as smart watches, smart bracelets, smart glasses, etc.), power banks, game consoles, digital multimedia players, and the like.

As shown in FIG. 11, an electronic device 10000 may include the memory system 1000 described above, and may further include at least one of a processor 2000 and a cache.

As an example, the processor 2000 may be a chip. Specifically, it may be a Field Programmable Gate Array (referred to as FPGA), an Application Specific Integrated Circuit (referred to as ASIC), a System on Chip (referred to as SoC), a Central Processor Unit (referred to as CPU), a Network Processor (referred to as NP), a Digital Signal Processor (referred to as DSP), a Micro Controller Unit (referred to as MCU), a Programmable Logic Device (referred to as PLD) or other integrated chips.

Implementations of the present disclosure provide a control method, a parameter calculation method, a memory and a memory system, which are capable of reducing the occupation of program processing time and storage space while improving the reliability and service life of the flash memory.

To achieve the above object, the implementations of the present disclosure adopt the following technical schemes.

In a first aspect, an implementation of the present disclosure provides a control method based on storage. The memory includes a plurality of memory cells and a plurality of first transistors. The plurality of memory cells correspond to the plurality of first transistors. The control method includes: reading the plurality of first transistors based on a first verification read voltage to obtain a first read failure count. A value of the first read failure count corresponds to a different product stage of the memory. A first voltage is stored in the plurality of first transistors. A voltage value of the first voltage is equal to that of the first verification read voltage. The product stage is associated with data processing times of the plurality of memory cells. The method further includes: selecting a destination entry from a plurality of entries according to the value of the first read failure count. The entry is to record processing parameters for data processing of the plurality of memory cells. The processing parameters include offset voltage value.

In the implementation of the present disclosure, the confirmation of the product stage of the memory cell M can be realized through a verification read operation. By selecting corresponding entries for different product stages, it is possible to improve the performance of data processing at the begining of memory stage (such as speeding up the processing of cycle programming), and improve the reliability of data processing at the end of life stage (such as the reliability of reading data). Verification reading are performed on the plurality of first transistors by using the first verification read voltage to obtain a first read failure count. The value of the first read failure count is associated with the data processing times of the plurality of memory cells. Therefore, different product stages may be determined for multiple memory cells according to the value of the first read failure count, and corresponding entries can be designed. Processing parameters for performing data processing operations on memory cells at different product stages are carried by different entries. In the subsequent work of the memory, it is only necessary to perform a program verification operation on the first transistor to confirm the current product stage of the multiple memory cells. The implementations of the present disclosure do not need to record and store data processing times after each data processing operation, which can improve memory processing performance, reduce memory processing time, and avoid occupying of the storage space by recording data processing times.

In some possible implementations, the aforementioned selecting a destination entry from a plurality of entries according to the value of the first read failure count includes: if the first read failure count is less than or equal to a first value, selecting a first destination entry from the plurality of entries, the first destination entry corresponding to a first product stage of the plurality of memory cells; and if the first read failure count is greater than the first value, selecting a second destination entry from the plurality of entries, the second destination entry corresponding to a second product stage of the plurality of memory cells. In an implementation of the present disclosure, a first value may be set, and the first value is a reference value for judging the read failure count. In the case that the first verification read voltage is the same, the first product stage and the second product stage are determined by the read failure count. Corresponding entries are respectively designed according to the first product stage and the second product stage. In actual programming, a program verification operation is performed by using the first verification read voltage, the corresponding first read failure count is obtained, and the first read failure count is compared with a preset first value. When the first read failure count is less than or equal to the first value, it means that the memory is in the first product stage at this time, and the first destination entry corresponding to the first product stage can be acquired. When the first read failure count is greater than the first value, it means that the memory is in the second product stage at this time, and the second destination entry corresponding to the second product stage can be acquired.

In some possible implementations, the first verification read voltage is a voltage value obtained from a first voltage set, the first voltage set includes a plurality of threshold voltages, and the plurality of threshold voltages are threshold voltages corresponding to the plurality of first transistors at a plurality of different programming times. In the implementations of the present disclosure, the performance change of the first transistor is positively correlated with the data processing times of the memory cell. The first verification voltage is to perform program verification on the plurality of memory cells after performing data processing on the plurality of memory cells. The performance change of the first transistor is positively correlated with the data processing times of the memory cell. Therefore, the first verification voltage can be obtained according to the performance change of the first transistor which is not a memory cell when the memory cell is subjected to different data processing times. The value of the first read failure count obtained by performing verification reading on the memory cell based on the first verification voltage may also indicate the data processing times of the memory cell.

In some possible implementations, the magnitude of the first verification read voltage is between a first threshold voltage and a second threshold voltage, the first threshold voltage is the threshold voltage corresponding to the first transistor at first programming times, the first programming times belongs to the programming times corresponding to the first product stage, the second threshold voltage is the threshold voltage corresponding to the first transistor at second programming times, and the second programming times belongs to the programming times corresponding to the second product stage. In an implementation of the present disclosure, a plurality of first transistors are read with the first verification read voltage to determine the first product stage and the second product stage, and the first verification read voltage can be selected as a voltage between the first threshold voltage and the second threshold voltage. The first threshold voltage is a threshold voltage at a certain first programming times corresponding to the first product stage. The second threshold voltage is a threshold voltage at a certain second programming times corresponding to the second product stage.

In some possible implementations, the first programming times is one-tenth of the second programming times. In an implementation of the present disclosure, the initial programming times of the first product stage may be set to one-tenth of the initial programming times of the second product stage. When the initial programming times of the first product stage is used as the first programming times and the initial programming times of the second product stage is used as the second programming times, the first verification voltage obtained based on the first programming times in conjunction with the second programming times is for verification reading of a plurality of first transistors, the first read failure count can be obtained to more precisely divide between the first product stage and the second product stage.

In some possible implementations, the first transistor is a program selection transistor or a dummy memory transistor. In an implementation of the present disclosure, the performance of the first transistor is changed as data processing times increase. In an actual memory, the performance of the program selection transistor or the dummy memory transistor will be affected by the increase in data processing times. Therefore, either the program selection transistor or the dummy memory transistor can be used as the first transistor. In some examples, the program select transistors may be TSG transistors, BSG transistors, or the like.

In some possible implementations, the offset voltage value includes program offset voltage value and/or read offset voltage value. The processing parameters further include program start voltage value and/or verify start voltage value. The control method also includes outputting a plurality of program voltages and/or a plurality of verification read voltages. The lowest voltage value of the plurality of program voltages is the program start voltage value. The lowest voltage value of the plurality of verification read voltages is controlled as a verify start voltage value for the plurality of verification read voltages with a read offset voltage value as a step unit. In the implementations of the present disclosure, the threshold voltage of the memory cell also changes as the data processing times increase. When the threshold voltage of a memory cell changes, its data processing parameters also change. For example, in the cycle programming method, the program start voltage value for programming and the verify start voltage value after programming need to be adaptively adjusted. At the same time, the program offset voltage value between multiple programming and the read offset voltage value between multiple verification operations in the cycle programming need to be adaptively adjusted. After determining the product stage, the appropriate destination entry is selected to perform cycle programming, which can increase the processing speed of programming and improve the reliability of reading.

In a second aspect, the implementations of the present disclosure provide a parameter calculation method, where the parameter calculation method is based on at least one memory. Each memory includes a plurality of memory cells and a plurality of first transistors. The plurality of memory cells correspond to the plurality of first transistors. The parameter calculation method includes: obtaining a first verification read voltage according to the plurality of first transistors, a first voltage being stored in the plurality of first transistors, and a voltage value of the first voltage being equal to that of the first verification read voltage; reading the plurality of first transistors based on the first verification read voltage to obtain a first read failure count; and according to the value of the first read failure count, determing different product stages for the plurality of memory cells of the at least one memory and obtaining a plurality of corresponding entries, the entries to record processing parameters for data processing of the plurality of memory cells, and the processing parameters including an offset voltage value.

In some possible implementations, according to the value of the first read failure count, aforementioned determining different product stages for the memory cells of the at least one memory and obtaining a plurality of corresponding entries, includes: if the first read failure count is less than or equal to a first value, determining that the corresponding plurality of memory cells are in a first product stage, and obtaining a first destination entry according to the first product stage; and if the first read failure count is greater than the first value, indicating that the corresponding memory cell is in a second product stage, and obtaining a second destination entry according to the second product stage.

In some possible implementations, the aforementioned obtaining the first verification read voltage according to the first transistor includes: obtaining a first voltage set according to the plurality of first transistors, the first voltage set includes a plurality of threshold voltages, the plurality of threshold voltages being threshold voltages corresponding to the plurality of first transistors at a plurality of different programming times; and obtaining the first verification read voltage according to the first voltage set.

In some possible implementations, the magnitude of the first verification read voltage is between a first threshold voltage and a second threshold voltage. The first threshold voltage is the threshold voltage corresponding to the plurality of first transistors at first programming times. The first programming times belongs to the programming times corresponding to the first product stage. The second threshold voltage is the threshold voltage corresponding to the plurality of first transistor at second programming times. The second programming times belongs to the programming times corresponding to the second product stage.

In some possible implementations, the first programming times is one-tenth of the second programming times.

In some possible implementations, the plurality of first transistors are program selection transistors or dummy memory transistors.

In some possible implementations, the offset voltage value includes a program offset voltage value and/or a read offset voltage value. Processing parameters also include program start voltage values and/or verify start voltage values.

In a third aspect, implementations of the present disclosure further provide a memory, which includes a control circuit, a register, a drive circuit, a program verification circuit, a plurality of memory cells, and a plurality of first transistors. The plurality of memory cells correspond to the plurality of first transistors. Multiple table entries are stored in the register. The drive circuit is configured to output a first verification read voltage to the plurality of first transistors. The first verification read voltage is to turn on and read the plurality of first transistors. The program verification circuit is configured to output a plurality of first indication signals to the control circuit. The plurality of first indication signals are to indicate the first read failure count corresponding to the plurality of first transistors. Values of the first read failure count correspond to different product stages of the plurality of memory cells. The product stage is associated with the data processing times of the plurality of memory cells. The control circuit is configured to select a destination entry from a plurality of entries in the register according to the value of the first read failure count. The entry is to record processing parameters for data processing of the plurality of memory cells. The processing parameters include offset voltage value.

In some possible implementations, the control circuit is further configured to: if the first read failure count is less than or equal to a first value, selecting a first destination entry from the plurality of entries, the first destination entry corresponding to a first product stage of the plurality of memory cells; and if the first read failure count is greater than the first value, selecting a second destination entry from the plurality of entries, the second destination entry corresponding to a second product stage of the plurality of memory cells.

In some possible implementations, the offset voltage value includes program offset voltage value and/or read offset voltage value. The processing parameters further include program start voltage value and/or verify start voltage value. The control circuit is further configured to: control the drive circuit to output a plurality of program voltages and/or a plurality of verification read voltages. The lowest voltage value of the plurality of program voltages is the program start voltage value. The lowest voltage value of the plurality of verification read voltages is controlled to be the verify start voltage value for the plurality of verification read voltages with the read offset voltage value as a step unit.

In a fourth aspect, an implementation of the present application further provides a memory system, where the memory system includes a controller and the memory as described in the third aspect. The controller is coupled to the memory.

In a fifth aspect, the implementation of the present application further provides an electronic device, where the electronic device includes a processor and the memory system as described in the fourth aspect. The processor is coupled to the memory system.

It can be understood that the beneficial effects that can be achieved by the parameter calculation method, memory, memory system, and electronic device provided by the above implementations of the present disclosure can refer to the beneficial effects of the control method above, and will not be repeated here.

The above description is only a specific implementation of the present disclosure, but the scope of protection is not limited thereto. Any changes or substitutions that can be easily conceived by those skilled in the art within the technical scope of this disclosure are all covered within the protective scope of the present application. Therefore, the protective scope of the present application should be determined by the protective scope of the claims.

What is claimed is:

1. A control method based on a memory, the memory comprising a plurality of memory cells and a plurality of transistors, the plurality of memory cells corresponding to the plurality of transistors; the control method comprising:
reading the plurality of transistors based on a verification read voltage to obtain a read failure count, values of the read failure count corresponding to different product stages of the memory, a voltage being stored in the plurality of transistors, a voltage value of the voltage being equal to that of the verification read voltage, and the product stages being associated with data processing times of the plurality of memory cells; and
selecting a destination entry from a plurality of entries according to a value of the read failure count, the entries to record processing parameters for data processing of the plurality of memory cells, and the processing parameters comprising an offset voltage value.

2. The control method of claim 1, wherein the selecting a destination entry from a plurality of entries according to the value of the read failure count comprises if the read failure count is less than or equal to a value, selecting a first destination entry from the plurality of entries, the first destination entry corresponding to a first product stage of the plurality of memory cells.

3. The control method of claim 1, wherein the selecting a destination entry from a plurality of entries according to the value of the read failure count comprises if the read failure count is greater than the value, selecting a second destination entry from the plurality of entries, the second destination entry corresponding to a second product stage of the plurality of memory cells.

4. The control method of claim 2, wherein the verification read voltage is a voltage value obtained from a voltage set, the voltage set comprises a plurality of threshold voltages, and the plurality of threshold voltages comprise threshold voltages corresponding to the plurality of transistors at a plurality of different programming times.

5. The control method of claim 4, wherein a magnitude of the verification read voltage is between a first threshold voltage and a second threshold voltage, the first threshold voltage is the threshold voltage corresponding to the transistors at first programming times; the first programming times belongs to programming times corresponding to the first product stage, the second threshold voltage is the threshold voltage corresponding to the transistors at second programming times, and the second programming times belongs to programming times corresponding to the second product stage.

6. The control method of claim 5, wherein the first programming times is one-tenth of the second programming times.

7. The control method of claim 4, wherein the transistors are program selection transistors or dummy memory transistors.

8. The control method of claim 1, wherein the offset voltage value comprises at least one of a program offset voltage value or a read offset voltage value, the processing parameters further comprise at least one of a program start voltage value or a verify start voltage value, and the control method further comprises:
outputting at least one of a plurality of program voltages and a plurality of verification read voltages;
setting a lowest voltage value of the plurality of program voltages as the program start voltage value; and
controlling a lowest voltage value of the plurality of verification read voltages to be the verify start voltage value for the plurality of verification read voltages with the read offset voltage value as a step unit.

9. A parameter calculation method based on a memory, the memory comprising a plurality of memory cells and a plurality of transistors, the plurality of memory cells corresponding to the plurality of transistors; the parameter calculation method comprising:
obtaining a verification read voltage according to the plurality of transistors, a voltage being stored in the plurality of transistors, and a voltage value of the voltage being equal to that of the verification read voltage;
reading the plurality of transistors based on the verification read voltage to obtain a read failure count; and
according to a value of the read failure count, determining different product stages for the plurality of memory cells of the memory and obtaining a plurality of corresponding entries, the entries to record processing parameters for data processing of the plurality of memory cells, and the processing parameters comprising an offset voltage value.

10. The parameter calculation method of claim 9, wherein according to the value of the read failure count, determining different product stages for the memory cells of the memory and obtaining a plurality of corresponding entries comprises if the read failure count is less than or equal to a value, determining that the corresponding plurality of memory cells are in a first product stage, and obtaining a first destination entry according to the first product stage.

11. The parameter calculation method of claim 9, wherein according to the value of the read failure count, determining different product stages for the memory cells of the memory and obtaining a plurality of corresponding entries comprises if the read failure count is greater than the value, determining that the corresponding memory cells are in a second product stage, and obtaining a second destination entry according to the second product stage.

12. The parameter calculation method of claim 11, wherein the obtaining the verification read voltage according to the transistors comprises obtaining a voltage set according to the plurality of transistors, the voltage set comprising a plurality of threshold voltages, and the plurality of threshold voltages comprising threshold voltages corresponding to the plurality of transistors at a plurality of different programming times.

13. The parameter calculation method of claim 11, wherein the obtaining the verification read voltage according to the transistors comprises obtaining the verification read voltage according to the voltage set.

14. The parameter calculation method of claim 13, wherein a magnitude of the verification read voltage is between a first threshold voltage and a second threshold voltage, the first threshold voltage is a threshold voltage corresponding to the plurality of transistors at first programming times; the first programming times belongs to programming times corresponding to the first product stage, the second threshold voltage is a threshold voltage corresponding to the plurality of transistors at second programming times, and the second programming times belongs to programming times corresponding to the second product stage.

15. The parameter calculation method of claim 11, wherein the plurality of transistors are program selection transistors or dummy memory transistors.

16. A memory comprising:
a register storing a plurality of entries;
a plurality of transistors;
a plurality of memory cells corresponding to the plurality of transistors;
a drive circuit configured to output a verification read voltage to the plurality of transistors, the verification read voltage to turn on and read the plurality of transistors;
a program verification circuit configured to output a plurality of indication signals to a control circuit, the plurality of indication signals to indicate a read failure count corresponding to the plurality of transistors, values of the read failure count corresponding to different product stages of the plurality of memory cells, and the product stages being associated with data processing times of the plurality of memory cells; and
the control circuit configured to select a destination entry from a plurality of entries in the register according to a value of the read failure count, the entries to record processing parameters for data processing of the plurality of memory cells, and the processing parameters comprising an offset voltage value.

17. The memory of claim 16, wherein the control circuit is further configured to, if the read failure count is less than or equal to a value, select a first destination entry from the plurality of entries, the first destination entry corresponding to a first product stage of the plurality of memory cells.

18. The memory of claim 16, wherein the control circuit is further configured to, if the read failure count is greater than the value, select a second destination entry from the plurality of entries, the second destination entry corresponding to a second product stage of the plurality of memory cells.

19. The memory of claim 17, wherein the offset voltage value comprises at least one of a program offset voltage value or a read offset voltage value, the processing parameters further comprise at least one of a program start voltage value or a verify start voltage value; the control circuit is further configured to control the drive circuit to output at least one of a plurality of program voltages or a plurality of verification read voltages.

20. The memory of claim 17, wherein the offset voltage value comprises at least one of a program offset voltage value or a read offset voltage value, the processing parameters further comprise at least one of a program start voltage value or a verify start voltage value; the control circuit is further configured to: set a lowest voltage value of the plurality of program voltages as the program start voltage value; and
control a lowest voltage value of the plurality of verification read voltages to be the verify start voltage value for the plurality of verification read voltages with the read offset voltage value as a step unit.
